(19) United States
(12) Patent Application Publication
(10) Pub. No.: US 2024/0312948 A1
(43) Pub. Date: Sep. 19, 2024

(54) SEMICONDUCTOR DEVICE

(71) Applicant: FUJI ELECTRIC CO., LTD., Kawasaki-shi (JP)

(72) Inventors: Yuichiro HINATA, Matsumoto-city (JP); Naoyuki KANAI, Matsumoto-city (JP)

(73) Assignee: FUJI ELECTRIC CO., LTD., Kawasaki-shi (JP)

(21) Appl. No.: 18/422,213

(22) Filed: Jan. 25, 2024

(30) Foreign Application Priority Data
Mar. 15, 2023 (JP) 2023-040650

(51) Int. Cl. H01L 23/00

(52) U.S. Cl. CPC H01L 24/48; H01L 24/40; H01L 24/73; H01L 2224/40227; H01L 2224/48227; H01L 2224/73221

(57) ABSTRACT

A semiconductor device includes: a semiconductor chip; a bonding wire electrically connected to an electrode provided on the semiconductor chip; and a connecting substrate jointed to the electrode of the semiconductor chip, in which: a thermal expansion coefficient of the connecting substrate is equal to a thermal expansion coefficient of the bonding wire, or the thermal expansion coefficient of the connecting substrate is within a range of the thermal expansion coefficient of the bonding wire or less and a first thermal expansion coefficient or greater, a difference between the first thermal expansion coefficient and the thermal expansion coefficient of the bonding wire is a predetermined value, and the bonding wire is jointed to the connecting substrate to be electrically connected to the electrode via the connecting substrate.

### CROSS REFERENCE TO RELATED APPLICATION

This Application is based on, and claims priority from, Japanese Patent Application No. 2023-040650, filed on Mar. 15, 2023, the entire contents of which are incorporated herein by reference.

### BACKGROUND

### Technical Field

The present disclosure relates to semiconductor devices.

### Related Art

Japanese Patent Application Laid-Open Publication No. 2011-253950 discloses occurrence of a problem in that cracks are generated early at a joint part of an Al wire that is jointed to a power semiconductor element in a semiconductor device under a load condition of high temperatures, resulting in failure to provide a desired service life. Japanese Patent Application Laid-Open Publication No. 2011-253950 discloses that stress applied to the joint part of the Al wire expanding due to high temperatures is decreased by provision of a buffer plate having a linear expansion coefficient that is intermediate between a linear expansion coefficient of the Al wire and that of the power semiconductor element.

WO2020/054688 discloses a semiconductor device that includes a base portion and a wire. The base portion is connected to a semiconductor element. The wire is connected to the base portion. In the semiconductor element, a linear expansion coefficient of the base portion is less than a linear expansion coefficient of a first conductive layer of the semiconductor element. WO2020/054688 discloses that this semiconductor device substantially prevents detachment of the wire.

In the techniques described in Japanese Patent Application Laid-Open Publication No. 2011-253950 and WO2020/054688, a difference in thermal expansion coefficient between a bonding wire and a member jointed to the bonding wire is relatively large. Thus, there is room for further improvement in reduction in distortion at a joint part of the bonding wire and there is room for further improvement in prevention of occurrence of cracks caused by the distortion.

### SUMMARY

An object of one aspect according to the present disclosure is to provide a semiconductor device capable of reducing occurrence of distortion at a joint part of a bonding wire.

A semiconductor device according to one aspect of the present disclosure includes: a semiconductor chip; a bonding wire electrically connected to an electrode provided on the semiconductor chip; and a connecting substrate jointed to the electrode of the semiconductor chip, in which: a thermal expansion coefficient of the connecting substrate is equal to a thermal expansion coefficient of the bonding wire, or the thermal expansion coefficient of the connecting substrate is within a range of the thermal expansion coefficient of the bonding wire or less and a first thermal expansion coefficient or greater, a difference between the first thermal expansion coefficient and the thermal expansion coefficient of the bonding wire is a predetermined value, and the bonding wire is jointed to the connecting substrate to be electrically connected to the electrode via the connecting substrate.

According to one aspect of the present disclosure, it is possible to reduce occurrence of distortion at a joint part of a wire.

### BRIEF DESCRIPTION OF THE DRAWINGS

FIG. 1 is a schematic cross section of an example of a semiconductor device according to an embodiment of the present disclosure.

FIG. 2 is a schematic plan view of the example of the semiconductor device.

FIG. 3 is a schematic cross section of an example of a connecting substrate.

FIG. 4 is a schematic plan view of the example of the connecting substrate.

FIG. 5 is a diagram showing differences in distortion at a joint part of a second wire dependent on whether the connecting substrate is present or not.

FIG. 6 is a diagram showing examples of materials used for the connecting substrate.

FIG. 7 is a flowchart showing an example of a manufacturing process of the semiconductor device.

FIG. 8 is a schematic plan view of an example of the connecting substrate according to a first modification of the present disclosure.

FIG. 9 is a schematic plan view of an example of the semiconductor device including the connecting substrate according to a second modification of the present disclosure.

### DESCRIPTION OF THE EMBODIMENTS

Embodiments according to the present disclosure will now be described with reference to the accompanying drawings. In each drawing, dimensions and scales of elements may differ from those of actual products. In addition, each embodiment described below is an exemplary embodiment assumed in a case in which the present disclosure is implemented. Thus, the scope of the present disclosure is not limited to the embodiments described below.

### 1. Embodiment

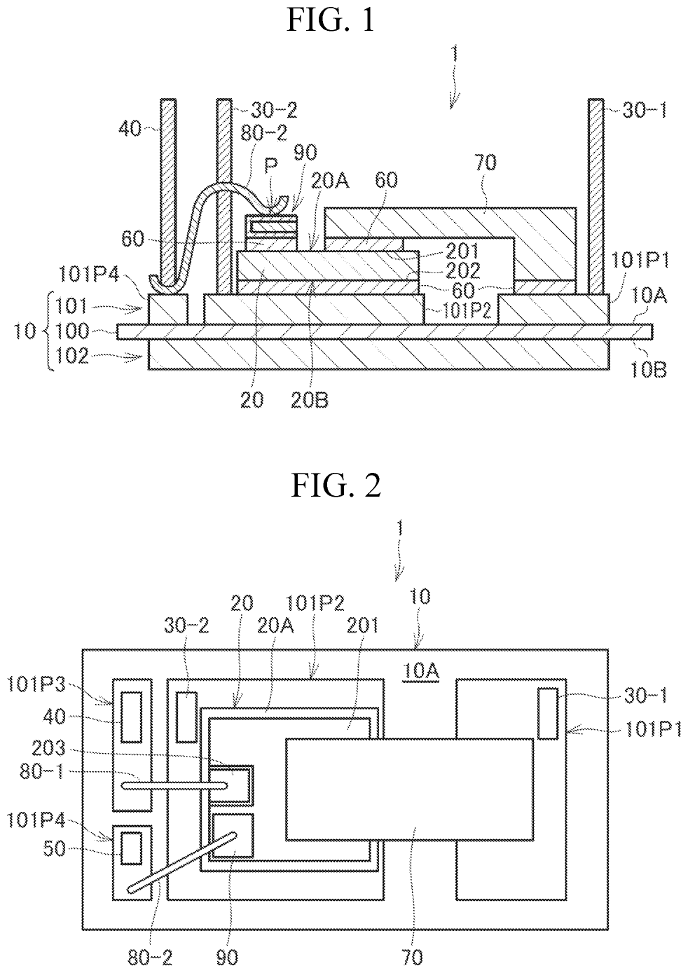

FIG. 1 is a schematic cross section of an example of a semiconductor device 1 according to an embodiment. FIG. 2 is a schematic plan view of the example of the semiconductor device 1. The semiconductor device 1 shown in FIGS. 1 and 2 is an example of a semiconductor device according to the present disclosure. As shown in FIG. 1, the semiconductor device 1 includes a plate-shaped insulated circuit board 10, a semiconductor chip 20, a first main terminal 30-1, a second main terminal 30-2, and a control terminal 40. The insulated circuit board 10 has a first main surface 10A and a second main surface 10B. The semiconductor chip 20 is disposed to be adjacent to the first main surface 10A of the insulated circuit board 10. The first main terminal 30-1, the second main terminal 30-2, and the control terminal 40 are each a terminal electrically connected to a corresponding electrode among different electrodes included in the semiconductor chip 20. The first main terminal 30-1, the second main terminal 30-2, and the control terminal 40 are connected to an external circuit that is separate from the semiconductor device 1.

In the following description, a direction from the insulated circuit board 10 toward the semiconductor chip 20 may be referred to as an “upward direction,” and a direction opposite to the upward direction may be referred to as a “downward direction.” In “plan view,” a target object is represented that is viewed from a point, which is above the target object, in the downward direction.

The insulated circuit board 10 includes a plate-shaped insulating layer 100 with electrical insulation. The insulating layer 100 has the first main surface 10A on which a first conductive layer 101 is disposed. The insulating layer 100 has the second main surface 10B on which a second conductive layer 102 is disposed. The insulating layer 100 may be made of an alumina (Al₂O₃) material, a ceramic matrix composite material that is mainly made of an alumina (Al₂O₃) material, an aluminum nitride (AlN) material, a silicon nitride (Si₃N₄) material, etc. The first conductive layer 101 and the second conductive layer 102 each include a pattern for constituting electrical circuits. The first conductive layer 101 and the second conductive layer 102 are each mainly made of a material that not only has excellent electrical conductivity, but also has excellent workability. This material is, for example, a metallic material such as a copper (Cu) material, an aluminum (Al) material, etc.

As shown in FIG. 2, the first conductive layer 101 includes a first pattern 101P1, a second pattern 101P2, and a third pattern 101P3. The first pattern 101P1 is connected to the first main terminal 30-1. The second pattern 101P2 is connected to the semiconductor chip 20 and to the second main terminal 30-2. The third pattern 101P3 is connected to the control terminal 40. In this embodiment, the semiconductor device 1 further includes an auxiliary terminal 50. The first conductive layer 101 further includes a fourth pattern 101P4 that is connected to the auxiliary terminal 50. To joint each of the first main terminal 30-1, the second main terminal 30-2, the control terminal 40, and the auxiliary terminal 50 to a corresponding pattern, an appropriate joint method such as solder joint, ultrasonic joint, or laser welding is used. A shape, a material, and a manufacturing method of each of the first main terminal 30-1, the second main terminal 30-2, the control terminal 40, and the auxiliary terminal 50 may be freely selected. In FIG. 1, the auxiliary terminal 50 is omitted.

As shown in FIG. 1, the semiconductor chip 20 according to this embodiment is a plate-shaped electronic component. The plate-shaped electronic component is mainly made of a silicon (Si) material, a silicon carbide (SiC) material, a gallium nitride (GaN) material, etc. In plan view, the plate-shaped electronic component has a substantially rectangular shape. The plate-shaped electronic component has a first main surface 20A and a second main surface 20B. As shown in FIG. 2, two different electrodes that include a first electrode 201 and a third electrode 203 are disposed on the first main surface 20A. As shown in FIG. 1, a second electrode 202 is disposed on the second main surface 20B. The second main surface 20B is jointed by a sintered material 60 to the second pattern 101P2. The sintered material 60 is a jointing material that is electrically conductive. The second electrode 202 of the semiconductor chip 20 and the second pattern 101P2 are electrically connected to each other via the sintered material 60.

As shown in FIG. 2, the first electrode 201 disposed on the first main surface 20A of the semiconductor chip 20 is electrically connected by a wiring member 70 to the first pattern 101P1. The third electrode 203 of the semiconductor chip 20 is electrically connected by a first wire 80-1 to the third pattern 101P3. In this embodiment, the first electrode 201 is electrically connected not only by the wiring member 70 to the first pattern 101P1, but also by a second wire 80-2 to the fourth pattern 101P4.

The first wire 80-1 and the second wire 80-2 are each a bonding wire that is mainly made of a metallic material such as an aluminum material, a copper material, etc. The first wire 80-1 has one end that is jointed by wire bonding to the third electrode 203. The first wire 80-1 has the other end that is jointed by wire bonding to the third pattern 101P3. The second wire 80-2 has one end that is jointed by wire bonding to the first electrode 201. The second wire 80-2 has the other end that is jointed by wire bonding to the fourth pattern 101P4. In this embodiment, the first electrode 201 is jointed by the sintered material 60 to a connecting substrate 90. The one end of the second wire 80-2 is connected by wire bonding to the connecting substrate 90. The connecting substrate 90 and the sintered material 60 will be described in detail below.

The wiring member 70 is a substantially plate-shaped conductive member that extends between the first electrode 201 and the first pattern 101P1. The wiring member 70 has a cross-section area greater than that of the bonding wire. Joint of the wiring member 70 to the first pattern 101P1 and to the first electrode 201 is performed using the sintered material 60 used for joint of the semiconductor chip 20 to the second pattern 101P2.

The wiring member 70 can carry a current larger than a current that can be carried by the bonding wire. Thus, it is possible to obtain the semiconductor device 1 that is appropriate for a larger current. A specific material and a shape of the wiring member 70 may be appropriately selected. For example, the wiring member 70 may be a plate-shaped member made of a metallic material such as a copper material.

The semiconductor chip 20 is an insulated gate bipolar transistor (IGBT), which is a power semiconductor element, or a switching element such as a metal-oxide-semiconductor field effect transistor (MOSFET), a bipolar junction transistor (BJT), etc., for example. In the following description, it is assumed that the semiconductor chip 20 comprises an IGBT. In this case, the first electrode 201 and the first main terminal 30-1 correspond to an emitter electrode and an emitter terminal, respectively. The second electrode 202 and the second main terminal 30-2 correspond to a collector electrode and a collector terminal, respectively. The third electrode 203 and the control terminal 40 correspond to a gate electrode and a gate terminal, respectively. The auxiliary terminal 50 corresponds to an auxiliary emitter terminal. In the semiconductor device 1, a control voltage to be applied to the control terminal 40 that is the gate terminal is controlled by an external circuit to control a current that flows between the first main terminal 30-1 (the emitter terminal) and the second main terminal 30-2 (the collector terminal).

A current flowing through the first main terminal 30-1 (the emitter terminal) is relatively large. Thus, due to influences of a voltage drop caused by the relatively large current, it may be difficult to accurately apply the control voltage between the first main terminal 30-1 (the emitter terminal) and the control terminal 40. To overcome the disadvantage, the auxiliary terminal 50 is used. As described above, the auxiliary terminal 50 as well as the first main terminal 30-1 is connected to the first electrode 201 (the emitter electrode). A current flowing through the auxiliary terminal 50 is significantly smaller than a current flowing through the first main terminal 30-1 (the emitter terminal). Thus, with application of a control voltage between the auxiliary terminal 50 and the control terminal 40 by an external device, the control voltage can be accurately applied between the first main terminal 30-1 and the control terminal 40 without being influenced by the voltage drop.

In this embodiment, the semiconductor device 1 is housed in a housing that includes a member, which is a radiator used as a base, and a frame fixed to the member used as a base. The semiconductor device 1 and the housing are modularized into a power semiconductor module. Such a power semiconductor module is, for example, used as an inverter circuit that drives an electric motor disposed in a vehicle, an industrial device, etc. In the inverter circuit, a pulse width modulation (PWM) signal that is repeatedly turned on and off is supplied to the control terminal 40 of the power semiconductor module. Changing a duty ratio, a frequency, etc., of the PWM signal causes control of turning on and off a current that flows between the first main terminal 30-1 (the emitter terminal) and the second main terminal 30-2 (the collector terminal). The control of turning the current on and off causes change in the number of revolutions, acceleration, etc., of the electric motor.

In the semiconductor device 1 incorporated in the power semiconductor module, with turning on and off the current that flows between the first main terminal 30-1 and the second main terminal 30-2, thermal cycling occurs at the semiconductor chip 20. In the thermal cycling, heat generation and cooling are repeated due to electrical resistance of the semiconductor chip 20. Thus, in a configuration in which a bonding wire is jointed by wire bonding to the electrode on the first main surface 20A of the semiconductor chip 20, distortion occurs dependent on the thermal cycling, the distortion being caused by a difference in thermal expansion coefficient between the semiconductor chip 20 and a joint part of the bonding wire that is jointed to the electrode of the semiconductor chip 20. The distortion may cause occurrence of cracks in the bonding wire. The cracks may finally break the bonding wire, resulting in failure of the semiconductor device 1. In other words, before the semiconductor chip 20 and a joint part of the wiring member 70 are damaged, failure of the semiconductor device 1 occurs due to the cracks in the bonding wire. Thus, service life of the semiconductor device 1 may be shorter than an estimated service life.

For power semiconductor modules, an operation temperature range is increasing annually so as to meet demands for cost reduction of the semiconductor device 1 such as size reduction and simplification of a cooling mechanism. The recent operation temperature range has reached a temperature range of 200° C. or greater, whereas the previous operation temperature range was a temperature range of 175° C. or less. Thus, a temperature difference in the thermal cycling of the semiconductor chip 20 becomes greater. As a result, distortion is increased that occurs at a connection between the semiconductor chip 20 and the joint part of the bonding wire. Consequently, a disadvantage is significant in that cracks occur in the bonding wire.

To overcome this disadvantage, for example, a method may be conceived in which a low-heat-generating area, through which a large current cannot flow, expands in the semiconductor chip 20, and an auxiliary emitter electrode is provided on a part of the low-heat-generating area that is separate from an area immediately above an active portion of the first main surface 20A, and a bonding wire is jointed to the auxiliary emitter electrode. However, provision of the low-heat-generating area in the semiconductor chip 20 causes a new disadvantage in that the size and cost of the semiconductor chip 20 are increased.

In the semiconductor device 1 according to this embodiment, the connecting substrate 90 is jointed to the first electrode 201 that corresponds to a heat-generating area of the semiconductor chip 20, and one end portion of the second wire 80-2 that is a bonding wire is jointed by wire bonding to the connecting substrate 90, resulting in substantially preventing occurrence of cracks in the bonding wire.

As shown in FIG. 2, in the semiconductor device 1 according to this embodiment, the first wire 80-1 as well as the second wire 80-2 is jointed by wire bonding to the first main surface 20A of the semiconductor chip 20. In the semiconductor chip 20 according to this embodiment, an area that corresponds to the third electrode 203 (the gate electrode in this embodiment) jointed to the first wire 80-1 is a low-heat-generating area described above. Thus, it is possible to sufficiently reduce occurrence of distortion at a joint part of the first wire 80-1. The first electrode 201 (the emitter electrode in this embodiment) corresponds to a heat-generating area. The first electrode 201 is jointed not only to the second wire 80-2, but also to the wiring member 70. However, joint strength of the wiring member 70 is greater than that of the second wire 80-2. Thus, assuming the joint part of the wiring member 70 breaks due to thermal cycling, the joint part of the second wire 80-2 breaks prior to breakage of the joint part of the wiring member 70. Accordingly, to prevent the service life of the semiconductor device 1 from being shortened, it is essential to prevent breakage of the second wire 80-2 rather than breakage of the wiring member 70.

### Structure and Characteristics of Connecting Substrate 90

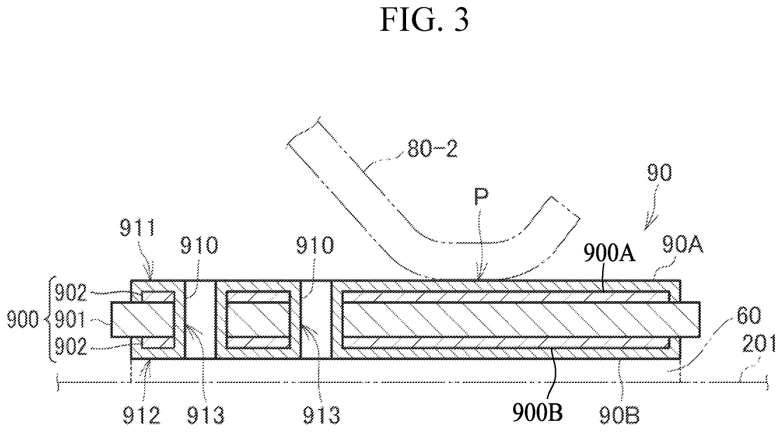

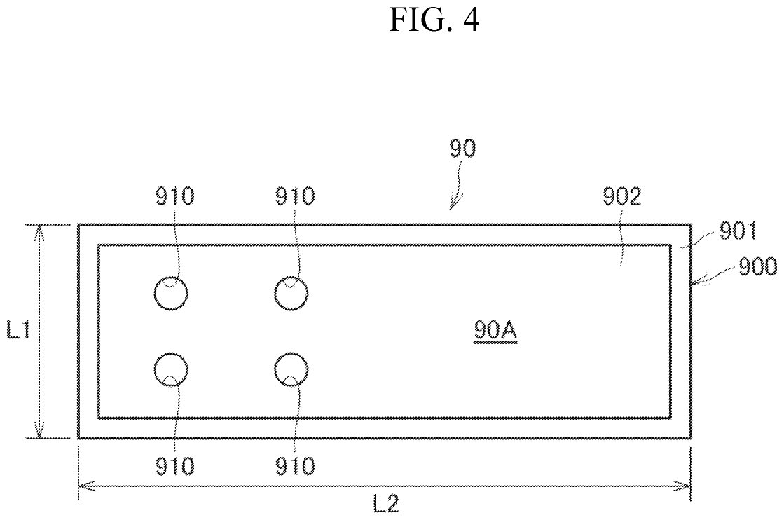

FIG. 3 is a schematic cross section of an example of the connecting substrate 90. FIG. 4 is a schematic plan view of the example of the connecting substrate 90. As shown in FIG. 3, the connecting substrate 90 is a plate-shaped member that has a first main surface 90A and a second main surface 90B. The first main surface 90A is jointed by wire bonding to the second wire 80-2. The second main surface 90B is jointed by the sintered material 60 to the first electrode 201 of the semiconductor chip 20. The connecting substrate 90 has a structure in which the first main surface 90A and the second main surface 90B are electrically connected to each other, and it is difficult for heat to be conducted between the first main surface 90A and the second main surface 90B. In addition, a thermal expansion coefficient α1 of the connecting substrate 90 is equal to a thermal expansion coefficient α2 of the second wire 80-2, or alternatively, the thermal expansion coefficient α1 of the connecting substrate 90 is within a range of the thermal expansion coefficient α2 of the second wire 80-2 or less and a first thermal expansion coefficient A1 or greater. A difference between the first thermal expansion coefficient A1 and the thermal expansion coefficient α2 of the second wire 80-2 is a predetermined value d. The thermal expansion coefficient α1 is a thermal expansion coefficient of the connecting substrate 90 in a range of 100° C. or greater and 200° C. or less, the range being assumed to be a range of high temperatures in which the semiconductor chip 20 operates. The thermal expansion coefficient α2 of the second wire 80-2 is an example of a value dependent on the thermal expansion coefficient α2 of the second wire 80-2.

Specifically, as shown in FIG. 3, the connecting substrate 90 according to this embodiment includes a first substrate 900, a first wiring layer 911, a second wiring layer 912, and at least one third wiring layer 913. The first substrate 900 has at least one through hole 910 penetrating between the first main surface 90A and the second main surface 90B. The first wiring layer 911 is conductive. The first wiring layer 911 is provided on a first main surface 900A of the first substrate 900. The second wiring layer 912 is conductive. The second wiring layer 912 is provided on a second main surface 900B of the first substrate 900. The third wiring layer 913 is conductive. The third wiring layer 913 is provided on a wall surface of the through hole 910. The third wiring layer 913 electrically connects the first wiring layer 911 and the second wiring layer 912 to each other. The first wiring layer 911, the second wiring layer 912, and the third wiring layer 913 are formed, for example, by plating processing.

The first substrate 900 is a plate material that has a low thermal conductivity less than or equal to one-tenth of the thermal conductivity of the insulated circuit board 10. The first substrate 900 has electrical insulation. The thermal conductivity of the insulated circuit board 10 can be less than or equal to 5 W/mK. In this embodiment, a printed circuit board is used as the first substrate 900. The first substrate 900 has an insulating plate 901 and a metallic foil 902. The insulating plate 901 is constituted of a base having not only a low thermal conductivity, but also electrical insulation. The insulating plate 901 has a first main surface and a second main surface. The metallic foil 902 is provided on each of the first main surface and the second main surface of the insulating plate 901 in a size to cover substantially the entire surface of each of the first main surface and the second main surface of the insulating plate 901. The printed circuit board may be either a rigid board or a flexible board. The metallic foil 902 may be a copper foil.

The first main surface 90A of the connecting substrate 90 has a dimension that is greater than or equal to a dimension of an area to which the second wire 80-2 can be jointed by wire bonding and that is less than or equal to a dimension of the first main surface 20A of the semiconductor chip 20. In this embodiment, the diameter of the second wire 80-2 is about 300 micrometers (μm). The first main surface 90A has a short side L1 of about 1 millimeter (mm) and a long side L2 of about 2 mm. As shown in FIG. 3, the first wiring layer 911 constituted of the first main surface 90A is jointed by wire bonding to the second wire 80-2. The second wiring layer 912 is jointed by the sintered material 60 to the first electrode 201 of the semiconductor chip 20. These joint cause the second wire 80-2 and the first electrode 201 to be electrically connected to each other via the first wiring layer 911, the second wiring layer 912, and the third wiring layer 913.

In a state in which the second wire 80-2 is connected to the connecting substrate 90, the first substrate 900 with thermal conductivity less than that of the semiconductor chip 20 is interposed between the second wire 80-2 and the first electrode 201. Thus, when the semiconductor chip 20 generates heat, it is difficult for the heat to be conducted from the semiconductor chip 20 to a joint part P of the second wire 80-2. The joint part P of the second wire 80-2 is jointed to the connecting substrate 90.

In general, it is known that distortion ε generated at the joint part P of the second wire 80-2 that is jointed to the connecting substrate 90 is proportional to a temperature change ΔT at the joint part P. In addition, it is known that the distortion ε is proportional to a thermal expansion coefficient difference Δα that is a difference between the thermal expansion coefficient α2 of the second wire 80-2 and the thermal expansion coefficient α1 of the connecting substrate 90 (where Δα=α2−α1).

Thus, with a reduction in heat transfer from the semiconductor chip 20 to the joint part P of the second wire 80-2 that is jointed to the connecting substrate 90, the temperature change ΔT is reduced at the joint part P, resulting in reducing the distortion ε. As a result, it is possible not only to reduce occurrence of cracks caused by the distortion ε at the joint part P of the second wire 80-2 that is jointed to the connecting substrate 90, but also to substantially prevent shortening of the service life of the semiconductor device 1.

As described above, the thermal expansion coefficient α1 of the connecting substrate 90 is set to a value within the range of the thermal expansion coefficient α2 of the second wire 80-2 or less and the first thermal expansion coefficient A1 (the first thermal expansion coefficient A1=the thermal expansion coefficient α2−the predetermined value d) or greater. In this embodiment, the predetermined value d is equal to about 9 ppm/K. Thus, the thermal expansion coefficient difference Δα is a small value that is greater than or equal to zero and that is less than or equal to the predetermined value d. As a result, the distortion ε is reduced further by the thermal expansion coefficient difference Δα being small. The predetermined value d is set dependent on the service life of a product that is desired. The distortion can be reduced with a reduction in the predetermined value d.

As described above, the connecting substrate 90 according to this embodiment is a stack of the first substrate 900, the first wiring layer 911, and the second wiring layer 912. Thus, the thermal expansion coefficient α1 of the connecting substrate 90 can be obtained using a rule of mixture of the linear thermal expansion coefficient (Turner, P. S. J. Research of the National Bureau of Standard 36, 239 1946) as described in Japanese Patent Application Laid-Open Publication No. 2021-150458, for example.

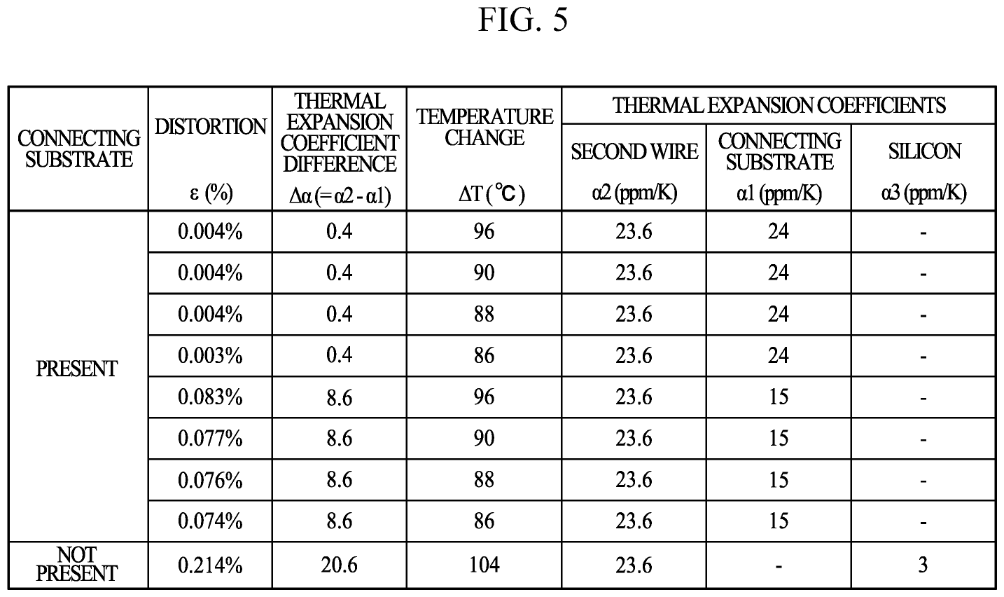

FIG. 5 is a diagram showing differences between distortions ε at the joint part P of the second wire 80-2, which is jointed to the connecting substrate 90. Each of the distortions ε is dependent on whether the connecting substrate 90 is present or not. The distortions ε at the joint part P are calculated not only based on the thermal expansion coefficient of the second wire 80-2, but also based on a thermal expansion coefficient of a member jointed to the second wire 80-2. Temperature changes ΔT in shown FIG. 5 are each a temperature change at the joint part P when a temperature is changed in thermal cycling from a room temperature to a high temperature. The temperature changes ΔT are obtained by a simulation in which it is assumed that the thermal conductivity of the connecting substrate 90 is equal to 0.4 W/mK. From results of this simulation, it will be understood that a temperature at the joint part P in a state in which the connecting substrate 90 is “present” is about 10° C. or more lower than a temperature at the joint part P in a state in which the connecting substrate 90 is “not present.”

In FIG. 5, the thermal expansion coefficient α2 of the second wire 80-2 is equal to that of a typical aluminum wire. In a state in which the connecting substrate 90 is “present,” the thermal expansion coefficient of the member jointed to the second wire 80-2 is equal to the thermal expansion coefficient α1 of the connecting substrate 90. In a state in which the connecting substrate 90 is “not present,” the thermal expansion coefficient of the member jointed to the second wire 80-2 is equal to the thermal expansion coefficient α3 of the semiconductor chip 20. A thermal expansion coefficient of a silicon (Si) material is used as the thermal expansion coefficient α3. Either a thermal expansion coefficient (=24) of an aluminum (Al) material or a thermal expansion coefficient (=15) of a copper (Cu) material is used as the thermal expansion coefficient α1 of the connecting substrate 90.

As shown in FIG. 5, in a state in which the connecting substrate 90 is “not present,” a distortion ε reaches about 0.2 percent. In contrast, in a state in which the thermal expansion coefficient α1 of the connecting substrate 90 is equal to the thermal expansion coefficient of an aluminum material, in other words, in a state in which the thermal expansion coefficient α1 of the connecting substrate 90 is substantially equal to the thermal expansion coefficient α2 of the second wire 80-2, a distortion ε is about 0.004 percent, which is significantly less than a distortion ε in a state in which the connecting substrate 90 is “not present.” Thus, it will be understood that it is significantly difficult for cracks to occur at the joint part P in this state compared to a state in which the connecting substrate 90 is “not present.”

In a state in which the thermal expansion coefficient α1 of the connecting substrate 90 is equal to the thermal expansion coefficient of a copper material, in other words, in a state in which the thermal expansion coefficient α1 of the connecting substrate 90 is equal to about 8 to 9 ppm/K less than the thermal expansion coefficient α2 of the second wire 80-2, a distortion ε is reduced to 0.08 percent. This value (0.08 percent) is about one third of the distortion ε caused in the state in which the connecting substrate 90 is “not present.” Thus, it will be understood that distortion ε is sufficiently reduced and occurrence of cracks is substantially prevented even when the difference between the thermal expansion coefficient α2 of the second wire 80-2 and the thermal expansion coefficient α1 of the connecting substrate 90, which is the predetermined value d, is about 8 to 9 ppm/K.

### Material Examples of Connecting Substrate 90

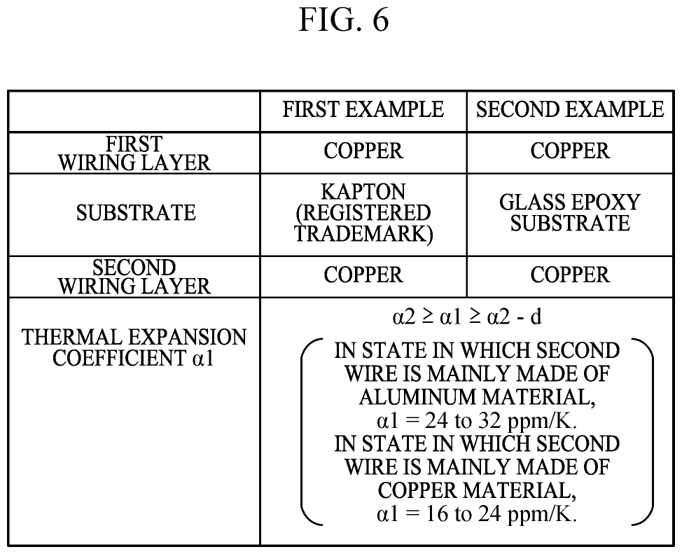

FIG. 6 is a diagram showing two examples of materials for the connecting substrate 90. In FIG. 6, a first example and a second example are each an example of materials for the connecting substrate 90. The materials for the connecting substrate 90 cause the thermal expansion coefficient α1 to be close to a thermal expansion coefficient of either an aluminum (Al) material or a copper (Cu) material. The materials for the connecting substrate 90 cause thermal conductivity of the first substrate 900 to be equivalent to the low thermal conductivity described above. In addition, the materials for the connecting substrate 90 allow the first substrate 900 to withstand application of pressure and heat necessary for making the sintered material 60. In the first example, the connecting substrate 90 has flexibility as a flexible substrate. In the second example, the connecting substrate 90 does not have flexibility as a rigid substrate. The first wiring layer 911 and the second wiring layer 912 may be each mainly made of a copper (Cu) material as indicated by the first example and by the second example, or alternatively the first wiring layer 911 and the second wiring layer 912 may be each mainly made of an aluminum (Al) material. The first substrate 900 may be mainly made of a polyimide material such as Kapton (registered trademark) for a flexible substrate, or alternatively the first substrate 900 may be mainly made of a glass epoxy material for a rigid substrate. In any combination of the materials in the first example or in the second example, it is possible to cause the thermal expansion coefficient α1 of the connecting substrate 90 to be close to a thermal expansion coefficient of either an aluminum material or a copper material by adjustment of a thickness of each of the first wiring layer 911, the second wiring layer 912, and the first substrate 900.

### Sintered Material 60 for Connecting Substrate 90

As described above, the sintered material 60 with conductivity is used to joint the connecting substrate 90 and the semiconductor chip 20 to each other. The sintered material 60 is the same as the jointing material used to joint the wiring member 70 and the first electrode 201 to each other. Thus, in a manufacturing process, after application of the sintered material 60 for joint of the wiring member 70 and the semiconductor chip 20 to each other, it is unnecessary to apply another jointing material for joint of the connecting substrate 90, resulting in reduced manufacturing cost.

In a state in which shear strength of a connection between the connecting substrate 90 and the semiconductor chip 20 is less than shear strength of the joint part P of the second wire 80-2 that is jointed to the connecting substrate 90, the connection between the connecting substrate 90 and the semiconductor chip 20 may break before the joint part P breaks. Thus, the connecting substrate 90 and the semiconductor chip 20 are jointed to each other using a jointing material that can provide shear strength greater than shear strength of a connection between the second wire 80-2 and the first electrode 201 jointed by wire bonding to the second wire 80-2. Specifically, the connecting substrate 90 and the semiconductor chip 20 are jointed to each other using the sintered material 60 that is a sintered jointing material. For example, the sintered jointing material is mainly made of silver particles or of copper particles. Shear strength (MPa) of each of these elements can be measured by a shear test based on JIS Z 3198-7 (a shear testing method of a solder join for a chip component).

### Manufacturing Process of Semiconductor Device 1

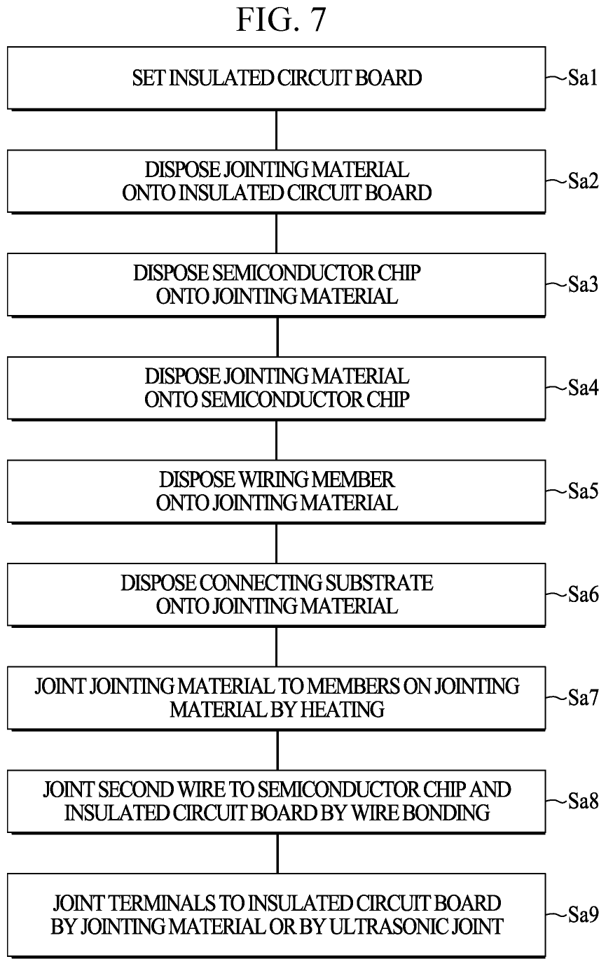

FIG. 7 is a flowchart showing an example of a manufacturing process of the semiconductor device 1. As shown in FIG. 7, first, the insulated circuit board 10 is set onto a stage of a manufacturing device (Step Sa1), and then a jointing material is disposed by application onto the first pattern 101P1 and the second pattern 101P2 on the first main surface 10A of the insulated circuit board 10 (Step Sa2). In this embodiment, the sintered material 60 is made from this jointing material. The sintered material 60 on the first pattern 101P1 and the sintered material 60 on the second pattern 101P2 may be made from a common jointing material. Next, the semiconductor chip 20 is disposed onto the jointing material (Step Sa3).

Next, a jointing material is disposed by application onto the first main surface 20A of the semiconductor chip 20 (Step Sa4). In this embodiment, the sintered material 60 disposed on the semiconductor chip 20 is made from this jointing material. This sintered material 60 disposed on the semiconductor chip 20 may be made from a jointing material different from the jointing material on the first pattern 101P1 and from the jointing material on the second pattern 101P2. Next, the wiring member 70 is disposed onto this jointing material (Step Sa5) and the connecting substrate 90 is disposed onto this jointing material (Step Sa6). As described above, the jointing material is used not only to joint the wiring member 70 and the semiconductor chip 20 to each other, but also to joint the connecting substrate 90 and the semiconductor chip 20 to each other. Thus, it is unnecessary to apply at Step Sa6 a jointing material different from the jointing material applied at Step Sa5.

Next, the insulated circuit board 10 on which members including the semiconductor chip 20 are disposed is placed in a heating furnace and is heated to change the jointing materials into the sintered materials 60 that join the members disposed on the jointing materials (Step Sa7). Next, one end of the second wire 80-2 is jointed by wire bonding to the connecting substrate 90, whereas the other end of the second wire 80-2 is jointed by wire bonding to the fourth pattern 101P4 of the insulated circuit board 10 (Step Sa8). Next, different terminals such as the first main terminal 30-1, the second main terminal 30-2, the control terminal 40, and the auxiliary terminal 50 are jointed, for example, by ultrasonic joint or by solder joint to the insulated circuit board 10 (Step Sa9).

As described above, the semiconductor device 1 according to this embodiment includes the semiconductor chip 20, the second wire 80-2 electrically connected to the first electrode 201 provided on the semiconductor chip 20, and the connecting substrate 90 jointed to the first electrode 201 of the semiconductor chip 20. The thermal expansion coefficient α1 of the connecting substrate 90 is equal to the thermal expansion coefficient α2 of the second wire 80-2, or the thermal expansion coefficient α1 of the connecting substrate 90 is within the range of the thermal expansion coefficient α2 of the second wire 80-2 or less and the first thermal expansion coefficient A1 or greater. The difference between the first thermal expansion coefficient A1 and the thermal expansion coefficient α2 of the second wire 80-2 is the predetermined value d. The second wire 80-2 is jointed to the connecting substrate 90 to be electrically connected to the first electrode 201 via the connecting substrate 90. According to this configuration, the thermal expansion coefficient α1 of the connecting substrate 90 is equal to the thermal expansion coefficient α2 of the second wire 80-2, or the thermal expansion coefficient α1 of the connecting substrate 90 is within the range of the thermal expansion coefficient α2 of the second wire 80-2 or less and the first thermal expansion coefficient A1 or greater. Thus, it is possible to reduce distortion ε generated in the thermal cycling of the semiconductor chip 20 and to substantially prevent occurrence of cracks due to the distortion ¿.

In the semiconductor device 1 according to this embodiment, the shear strength of the connection between the connecting substrate 90 and the first electrode 201 is greater than the shear strength of the connection between the second wire 80-2 and the first electrode 201 jointed by wire bonding to the second wire 80-2. According to this configuration, it is possible to reliably prevent occurrence of breakage such as cracks at the connection between the connecting substrate 90 and the first electrode 201 prior to occurrence of breakage such as cracks at the joint part P of the second wire 80-2 jointed to the connecting substrate 90.

The semiconductor device 1 according to this embodiment further includes the insulated circuit board 10 on which the semiconductor chip 20 is disposed, and the plate-shaped wiring member 70 electrically connecting the first electrode 201 and the insulated circuit board 10 to each other. The jointing material used to joint the connecting substrate 90 and the first electrode 201 to each other is used to joint the wiring member 70 and the first electrode 201 to each other. According to this configuration, after the jointing material for joint of the wiring member 70 and the semiconductor chip 20 to each other is applied to the semiconductor chip 20, it is unnecessary to apply another jointing material that is different from the applied jointing material, to joint the connecting substrate 90, resulting in reduced manufacturing cost.

In the semiconductor device 1 according to this embodiment, the thermal conductivity of the connecting substrate 90 is less than the thermal conductivity of the semiconductor chip 20. According to this configuration, the connecting substrate 90 with the thermal conductivity less than the thermal conductivity of the semiconductor chip 20 is interposed between the second wire 80-2 and the first electrode 201. Thus, when the semiconductor chip 20 generates heat, it is difficult for the heat to be conducted from the semiconductor chip 20 to the joint part P of the second wire 80-2, the joint part P of the second wire 80-2 being jointed to the connecting substrate 90, resulting in reducing the distortion ε generated at the joint part P.

In the semiconductor device 1 according to this embodiment, the connecting substrate 90 includes the first substrate 900, the first wiring layer 911, the second wiring layer 912, and the at least one third wiring layer 913. The first substrate 900 has the first main surface 900A, the second main surface 900B, and the at least one through hole 910 penetrating between the first main surface 900A and the second main surface 900B. The first wiring layer 911 is conductive. The first wiring layer 911 is provided on the first main surface 900A. The first wiring layer 911 is jointed to the second wire 80-2. The second wiring layer 912 is conductive. The second wiring layer 912 is provided on the second main surface 900B. The second wiring layer 912 is jointed to the first electrode 201 of the semiconductor chip 20. The third wiring layer 913 is conductive. The third wiring layer 913 is provided on the wall surface of the through hole 910. The third wiring layer 913 electrically connects the first wiring layer 911 and the second wiring layer 912 to each other. According to this configuration, while the through hole 910 electrically connects the first wiring layer 911 and the second wiring layer 912 to each other, the insulating plate 901 of the first substrate 900 substantially prevents heat from being conducted from the second main surface 90B to the first main surface 90A. Thus, it is possible to reduce an increase in temperature at the joint part P of the second wire 80-2 jointed to the first main surface 90A. In addition, it is possible to adjust the electrical insulation, the thermal conductivity, and the thermal expansion coefficient α1 of the connecting substrate 90 by changing a main material, the thickness, etc., of each of the first substrate 900, the first wiring layer 911, and the second wiring layer 912.

### 2. Modifications

Specific modified modes that may be applied to each of the embodiments described above are described below. Two or more modifications freely selected from the following modifications may be combined as long as no conflict arises from such combination.

### First Modification

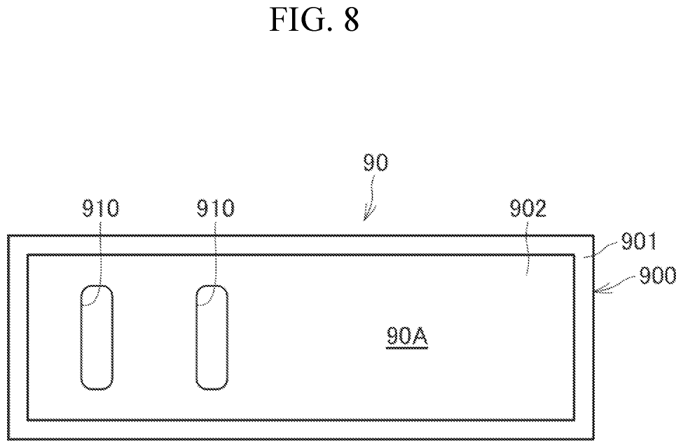

FIG. 8 is a schematic plan view of an example of the connecting substrate 90 according to a first modification. An opening shape of the at least one through hole 910 of the connecting substrate 90 viewed from the first main surface 90A is not limited to a circular shape as shown in FIG. 4. The opening shape of the at least one through hole 910 may be an elongated circular shape as shown in FIG. 8.

### Second Modification

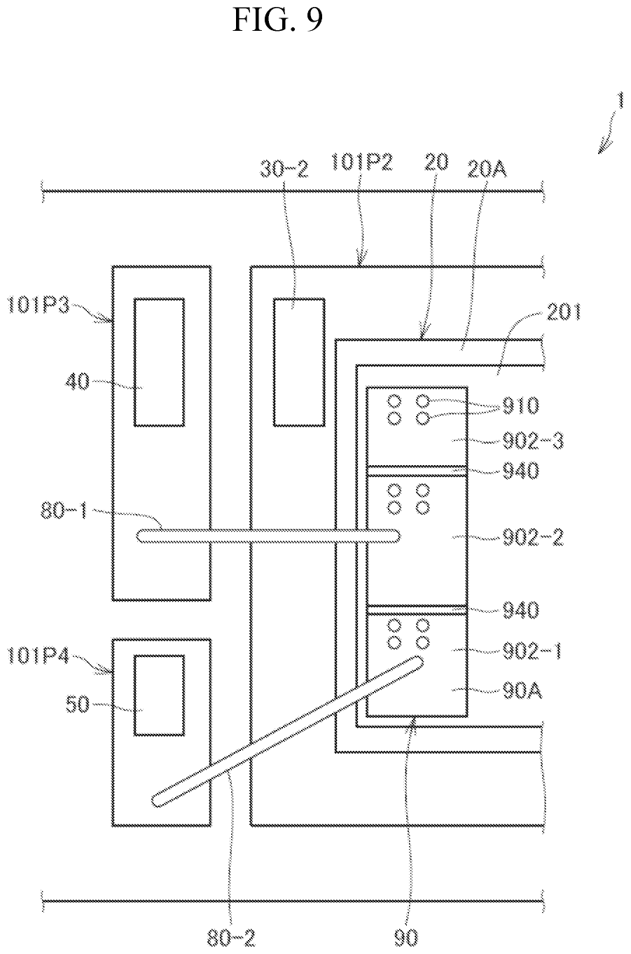

As shown in FIG. 9, the connecting substrate 90 may have a shape to cover both a part of the first electrode 201 and the third electrode 203 that are provided on the first main surface 20A of the semiconductor chip 20 (that is, a shape to cover a plurality of electrodes). In addition, both the second wire 80-2 electrically connected to the first electrode 201 and the first wire 80-1 electrically connected to the third electrode 203 may be jointed to the connecting substrate 90. More specifically, the first wiring layer 911, which constitutes the first main surface 90A of the connecting substrate 90, includes a first region 902-1, a second region 902-2, and a separation region 940. The first region 902-1 is electrically connected to the first electrode 201. The second region 902-2 is electrically connected to the third electrode 203. The separation region 940 electrically separates the first region 902-1 and the second region 902-2 from each other. The separation region 940 is formed by removing a part of the first wiring layer 911, for example. Although not shown, the second wiring layer 912, which constitutes the second main surface 90B, includes a region electrically connected to the first electrode 201, a region electrically connected to the third electrode 203, and a separation region. The separation region electrically separates the region electrically connected to the first electrode 201 and the region electrically connected to the third electrode 203 from each other. On the first main surface 90A, the first region 902-1 is jointed to the second wire 80-2, and the second region 902-2 is jointed to the first wire 80-1. In a case in which another electrode, which is electrically connected to a bonding wire for detection of a state of the temperature, etc., is further provided on the first main surface 20A of the semiconductor chip 20, the connecting substrate 90 may have a shape to further cover this electrode, and a third region 902-3 corresponding to this electrode may be further provided.

According to this modification, distortion caused by the thermal cycling of the semiconductor chip 20 is reduced in each of the bonding wires electrically connected to the semiconductor chip 20, and it is possible to reduce occurrence of cracks due to the distortion.

### Third Modification

The jointing material used to joint the connecting substrate 90 and the semiconductor chip 20 to each other may be different from the jointing material used to joint the semiconductor chip 20 and the wiring member 70 to each other. The jointing material used to joint the connecting substrate 90 and the semiconductor chip 20 to each other is not limited to a material for being sintered. In other words, the jointing material may be a material, such as solder that is reinforced by coating of a metallic adhesive or by coating of a resin material so as to have a significant shear strength as long as the material has conductivity and can provide shear strength greater than that of a joint part of a bonding wire in a state in which the bonding wire and the semiconductor chip 20 are jointed by wire bonding.

### DESCRIPTION OF REFERENCE SIGNS

1 . . . semiconductor device, 10 . . . insulated circuit board, 20 . . . semiconductor chip, 60 . . . sintered material (jointing material), 70 . . . wiring member, 80-1 . . . first wire (bonding wire), 80-2 . . . second wire (bonding wire), 90 . . . connecting substrate, 201 . . . first electrode, 202 . . . second electrode, 203 . . . third electrode, 910 . . . through hole, 911 . . . first wiring layer, 912 . . . second wiring layer, 913 . . . third wiring layer, P . . . joint part, d . . . predetermined value, α1, α2, α3 . . . thermal expansion coefficient.

What is claimed is:

1. A semiconductor device comprising:
a semiconductor chip;
a bonding wire electrically connected to an electrode provided on the semiconductor chip; and
a connecting substrate jointed to the electrode of the semiconductor chip,
wherein a thermal expansion coefficient of the connecting substrate is equal to a thermal expansion coefficient of the bonding wire, or the thermal expansion coefficient of the connecting substrate is within a range of the thermal expansion coefficient of the bonding wire or less and a first thermal expansion coefficient or greater,
wherein a difference between the first thermal expansion coefficient and the thermal expansion coefficient of the bonding wire is a predetermined value, and
wherein the bonding wire is jointed to the connecting substrate to be electrically connected to the electrode via the connecting substrate.

2. The semiconductor device according to claim 1, wherein shear strength of a connection between the connecting substrate and the electrode is greater than shear strength of a connection between the bonding wire and the electrode in a state in which the bonding wire and the electrode are jointed by wire bonding to each other.

3. The semiconductor device according to claim 2, further comprising:
an insulated circuit board on which the semiconductor chip is disposed; and
a plate-shaped wiring member electrically connecting the electrode and the insulated circuit board to each other,
wherein a jointing material used to joint the connecting substrate and the electrode to each other is used to joint the wiring member and the electrode to each other.

4. The semiconductor device according to claim 1, wherein thermal conductivity of the connecting substrate is less than thermal conductivity of an insulated circuit board on which the semiconductor chip is disposed.

5. The semiconductor device according to claim 1,
wherein the connecting substrate includes:
a substrate having a first main surface, a second main surface, and at least one through hole penetrating between the first main surface and the second main surface;
a first wiring layer that is conductive, the first wiring layer being provided on the first main surface and being jointed to the bonding wire;
a second wiring layer that is conductive, the second wiring layer being provided on the second main surface and being jointed to the electrode of the semiconductor chip; and
a third wiring layer that is conductive, the third wiring layer being provided on a wall surface of the through hole and coupling the first wiring layer and the second wiring layer to each other.

6. The semiconductor device according to claim 5, wherein an opening shape of the through hole viewed from the first main surface is an elongated circular shape.
